(19) United States
(12) Patent Application Publication
(10) Pub. No.: US 2012/0217610 A1
(43) Pub. Date: Aug. 30, 2012

(54) Bonded Semiconductor Structure With Pyramid-Shaped Alignment Openings and Projections

(76) Inventors: Peter J. Hopper, San Jose, CA (US); Peter Johnson, Sunnyvale, CA (US); Luu Nguyen, San Jose, CA (US); Peter Smeys, San Jose, CA (US)

(21) Appl. No.: 13/037,281

(22) Filed: Feb. 28, 2011

(51) Int. Cl. H01L 29/02; H01L 21/762

(52) U.S. Cl. 257/506; 438/455; 257/622; 257/E29.002; 257/E21.567

(57) ABSTRACT

A bonded semiconductor structure is formed in a method that first forms a female semiconductor structure with pyramid-shaped openings and a male semiconductor structure with pyramid-shaped projections, and then inserts the projections into the openings to align the male semiconductor structure to the female semiconductor structure for bonding.

### BACKGROUND OF THE INVENTION

1. Field of the Invention

The present invention relates to bonded semiconductor structures and, more particularly, to a bonded semiconductor structure with pyramid-shaped alignment openings and projections.

2. Description of the Related Art

Wafer bonding includes a number of well-known processes where two or more semiconductor structures, such as wafers or dice, are attached to each other to form a bonded semiconductor structure. For example, adhesive bonding, solder bonding, anodic bonding, fusion bonding, eutectic bonding, and glass frit bonding are each processes for bonding two or more semiconductor structures together.

Two or more semiconductor structures are bonded together in a number of semiconductor fabrication sequences. For example, stacked die structures are bonded semiconductor structures that are formed from bonding one semiconductor structure to the top surface of another semiconductor structure. In addition, many microelectromechanical systems (MEMS) devices are formed by bonding one semiconductor structure to the surface of another semiconductor structure.

Before a pair of semiconductor structures can be bonded together, the top semiconductor structure must be aligned to the bottom semiconductor structure. Where a high degree of precision is required, such as an alignment accuracy on the order of 1 μm, optical alignment is commonly used. Optical alignment systems, however, are quite expensive and tend to be relatively slow. As a result, there is a need for an inexpensive, fast, and highly precise method of aligning two semiconductor structures before the two semiconductor structures are wafer bonded together.

### BRIEF DESCRIPTION OF THE DRAWINGS

FIGS. 1A-1B through 4A-4B are views illustrating an example of a method of forming a female semiconductor wafer in accordance with the present invention. FIGS. 1A-4A are cross-sectional views, while FIGS. 1B-4B are cross-sectional views taken along lines 1B-1B through 4B-4B of FIGS. 1A-4A, respectively.

FIGS. 5A-5B through 8A-8B are views illustrating an example of a method of forming a male semiconductor wafer in accordance with the present invention. FIGS. 5A-8A are cross-sectional views, while FIGS. 5B-8B are cross-sectional views taken along lines 5B-5B through 8B-8B of FIGS. 4A-8A, respectively.

FIGS. 9-10 are cross-sectional views illustrating an example of a method of forming a bonded semiconductor structure 900 in accordance with the present invention.

FIG. 11 is a cross-sectional view illustrating an alternate example of bonded semiconductor structure 900 in accordance with the present invention.

FIGS. 12A-12B are views illustrating an example of the alignment error tolerance of semiconductor structure 900 in accordance with the present invention. FIG. 12A is a plan view, while FIG. 12B is a cross-sectional view taken along lines 12B-12B of FIG. 12A.

FIG. 13 is a cross-sectional view illustrating an example of a bonded semiconductor structure 1300 in accordance with an alternate embodiment of the present invention.

FIGS. 14A-14B through 23A-23B are views illustrating an example of a method of forming a female semiconductor wafer in accordance with the present invention. FIGS. 14A-23A are cross-sectional views, while FIGS. 14B-23B are cross-sectional views taken along lines 14B-14B through 23B-23B of FIGS. 14A-23A, respectively.

FIGS. 24A-24B through 33A-33B are views illustrating an example of a method of forming a male semiconductor wafer in accordance with the present invention. FIGS. 24A-33A are cross-sectional views, while FIGS. 24B-33B are cross-sectional views taken along lines 24B-24B through 33B-33B of FIGS. 24A-33A, respectively.

FIGS. 34-35 are cross-sectional views illustrating an example of a method of forming a bonded semiconductor structure 3400 in accordance with the present invention.

FIG. 36 is a cross-sectional view illustrating an example of a bonded semiconductor structure 3600 in accordance with an alternate embodiment of the present invention.

FIG. 37 is a cross-sectional view illustrating a further example of bonded semiconductor structure 3600 in accordance with an alternate embodiment of the present invention.

### DETAILED DESCRIPTION OF THE INVENTION

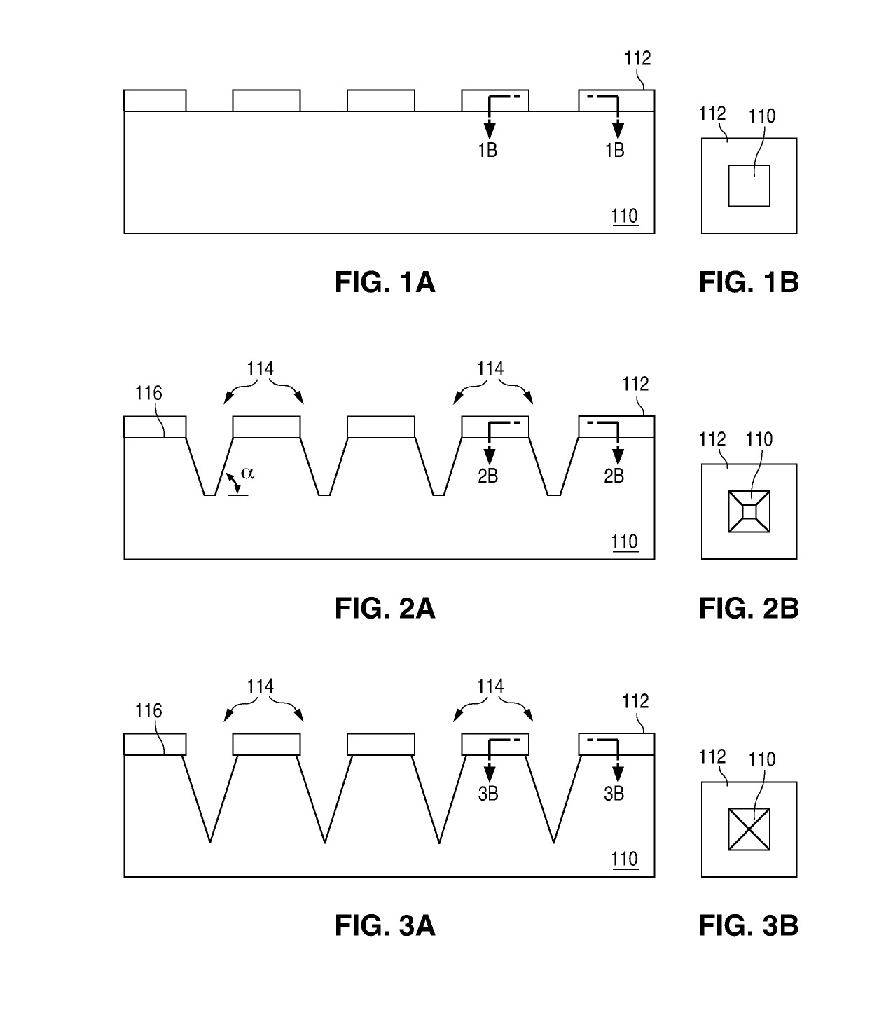

FIGS. 1A-1B through 4A-4B show views that illustrate an example of a method of forming a female semiconductor wafer in accordance with the present invention. FIGS. 1A-4A are cross-sectional views, while FIGS. 1B-4B are cross-sectional views taken along lines 1B-1B through 4B-4B of FIGS. 1A-4A, respectively.

As shown in FIGS. 1A-1B, the method utilizes a conventionally formed semiconductor wafer 110 that has a body material of, for example, silicon, gallium arsenic, or gallium nitride. As further shown in FIGS. 1A-1B, the method begins with any necessary grinding and polishing of the body material of semiconductor wafer 110 to define the thickness and smoothness of wafer 110, and continues by forming a hard mask 112 on the body material of semiconductor wafer 110.

Hard mask 112 can be formed in a conventional manner. For example, in one common approach, a layer of silicon nitride is deposited onto semiconductor wafer 110 by low-pressure chemical vapor deposition (LPCVD). Following this, a patterned photoresist layer is formed on the top surface of the layer of silicon nitride.

The patterned photoresist layer is also formed in a conventional manner, which includes depositing a layer of photoresist, and projecting a light through a patterned black/clear glass plate known as a mask to form a patterned image on the layer of photoresist. The light softens the photoresist regions exposed to the light. Following this, the softened photoresist regions are removed.

After the patterned photoresist layer has been formed, the exposed regions of the nitride layer are etched in a conventional manner to expose a large number of regions on the surface of semiconductor wafer 110, and thereby form hard mask 112. Thus, hard mask 112 has a pattern that is defined by the etch of the nitride layer. After the etch of the nitride layer, the patterned photoresist layer is removed.

As shown in FIGS. 2A-2B, after hard mask 112 has been formed, the exposed regions of wafer 110 are anisotropically wet etched in a conventional manner to form a number of alignment openings 114 in wafer 110. The alignment openings 114 extend into wafer 110 from a substantially planar surface 116 of wafer 110.

Wafer 110 is wet etched with an etchant, such as Tetra Methyl Ammonium Hydroxide (TMAH), Potassium Hydroxide (KOH), or KOH/Ethanol, that provides significantly different etch rates along the crystal planes. (KOH and KOH/ethanol may not be favored because of potential potassium contamination of the equipment.)

As further shown in FIGS. 2A-2B, the etch of wafer 110 forms each of the alignment openings 114 to have a flat-bottomed inverted pyramid shape. For example, an anisotropic wet etch of a <100> silicon wafer etches along the crystallographic planes to form the alignment openings 114 with flat-bottomed inverted pyramid shapes that have side wall angles a equal to 54.7°.

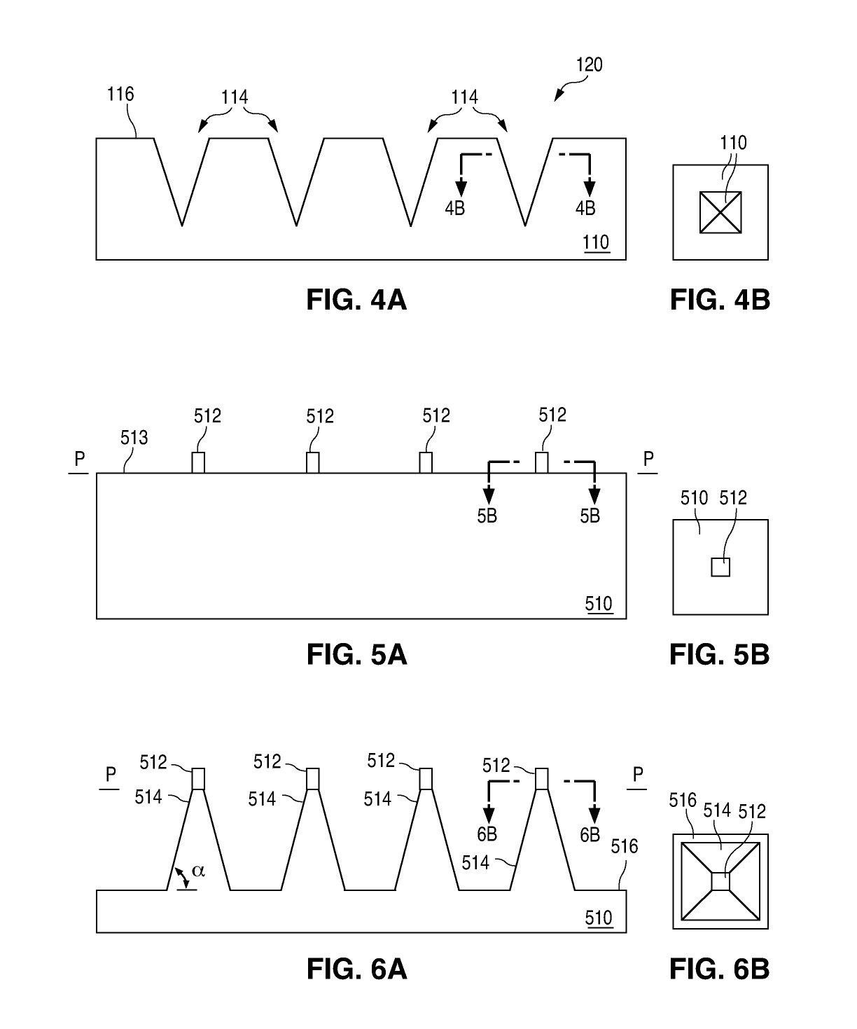

The etching can optionally be continued which, as shown in FIGS. 3A-3B, forms each of the alignment openings 114 to have an inverted pyramid shape that undercuts hard mask 112. As shown in FIGS. 4A-4B, following the etch, hard mask 112 is removed in a conventional manner to form a female semiconductor wafer 120.

FIGS. 5A-5B through 8A-8B show views that illustrate an example of a method of forming a male semiconductor wafer in accordance with the present invention. FIGS. 5A-8A are cross-sectional views, while FIGS. 5B-8B are cross-sectional views taken along lines 5B-5B through 8B-8B of FIGS. 4A-8A, respectively.

As shown in FIGS. 5A-5B, the method utilizes a conventionally formed semiconductor wafer 510 that has a body material of, for example, silicon, gallium arsenic, or gallium nitride. As further shown in FIGS. 5A-5B, the method begins with any necessary grinding and polishing of the body material of semiconductor wafer 510 to define the thickness and smoothness of wafer 510, and continues by forming a hard mask 512 on a surface 513 of the body material of semiconductor wafer 510 in a conventional manner.

As shown in FIGS. 6A-6B, after hard mask 512 has been formed, the exposed region on surface 513 of wafer 510 is anisotropically wet etched in a conventional manner to form a number of alignment projections 514 on wafer 510 that extend outward and away from a substantially planar etched surface 516 of wafer 510. Wafer 510 is etched with an etchant, such as Tetra Methyl Ammonium Hydroxide (TMAH), Potassium Hydroxide (KOH), or KOH/Ethanol, that provides significantly different etch rates along the crystal planes.

As further shown in FIGS. 6A-6B, the etch of wafer 510 forms each of the alignment projections 514 to have a flat-topped pyramid shape. For example, an anisotropic wet etch of a <100> silicon wafer etches along the crystallographic planes to form the alignment projections 514 with flat-topped pyramid shapes that have side wall angles a equal to 54.7°.

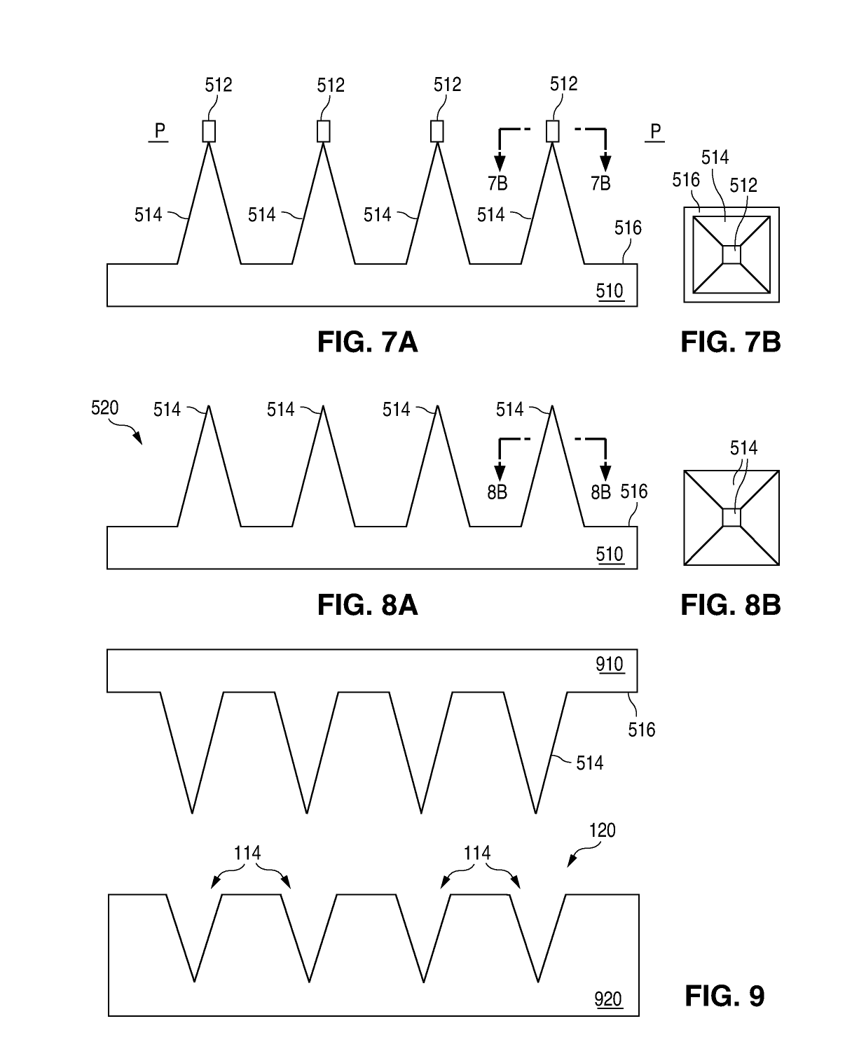

The etching can optionally be continued which, as shown in FIGS. 7A-7B, forms each of the alignment projections 514 to have a pyramid shape that undercuts hard mask 512. As shown in FIGS. 6A-6B and 7A-7B, the projections 514 are laterally or horizontally surrounded by and extend out away from etched surface 516. In addition, as shown in FIGS. 5A-5B, hard mask 512 and surface 513 of the body material of wafer 510 lie substantially in a plane P before the etch. However, as shown in FIGS. 6A-6B and 7A-7B, after the etch, only hard mask 512 and the projections 514 remain lying substantially in the plane P.

As shown in FIGS. 8A-8B, following the etch, hard mask 512 is removed in a conventional manner to form a male semiconductor wafer 520. As shown in FIGS. 1A-1B through FIGS. 8A-8B, the difference between the female and male semiconductor wafers 120 and 520 is the patterns of the hard masks 112 and 512.

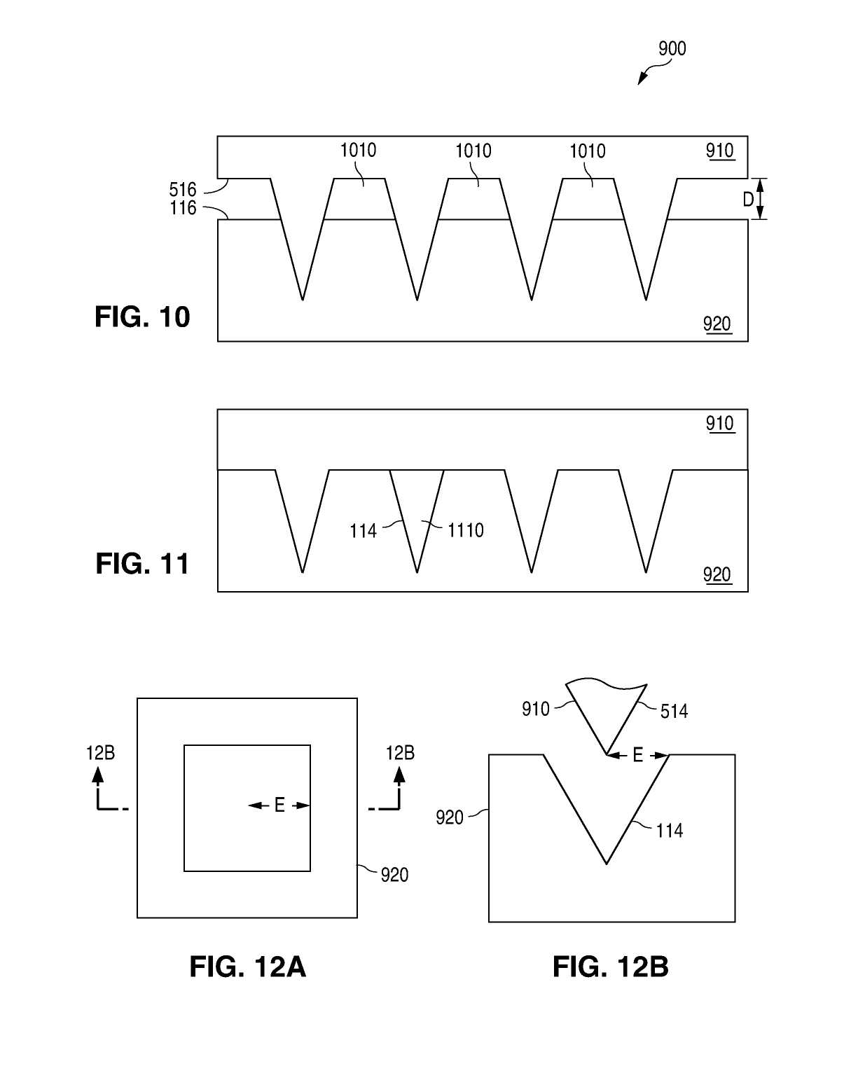

FIGS. 9-10 show cross-sectional views that illustrate an example of a method of forming a bonded semiconductor structure 900 in accordance with the present invention. As shown in FIG. 9, the method begins by positioning the tips of the alignment projections 514 of a male semiconductor structure 910 over the alignment openings 114 in a female semiconductor structure 920.

Male semiconductor structure 910 can be implemented with, for example, male semiconductor wafer 520 or a die diced from male semiconductor wafer 520, while female semiconductor structure 920 can be implemented with female semiconductor wafer 120 or a die diced from female semiconductor wafer 120.

Following this, as shown in FIG. 10, the method applies any necessary bonding materials, inserts male semiconductor structure 910 into female semiconductor structure 920, and bonds male semiconductor structure 910 to female semiconductor structure 920 to form bonded semiconductor structure 900.

As shown in FIGS. 9-10, the alignment openings 114 and the alignment projections 514 are in register so that each pyramid-shaped alignment projection 514 fits into a corresponding pyramid-shaped alignment opening 114. Male semiconductor structure 910 can be bonded to female semiconductor structure 920 to form bonded semiconductor structure 900 in a number of ways including, for example, adhesive bonding, anodic bonding, and fusion bonding.

In the FIG. 10 example, the planar surface 516 of structure 910 is separated from the planar surface 116 of structure 920 by a distance D, which can be varied by varying the sizes of the alignment openings 114 and the alignment projections 514. In addition, when the distance D is greater than zero, a number of die-to-die openings 1010, which can function as heat sink openings for a coolant, are formed when male semiconductor structure 910 is bonded to female semiconductor structure 920.

FIG. 11 shows a cross-sectional view that illustrates an alternate example of bonded semiconductor structure 900 in accordance with the present invention. The FIG. 11 example illustrates the case when the distance D is zero so that the planar surface 516 of structure 910 directly touches the planar surface 116 of structure 920. In addition, the FIG. 11 example illustrates that a heat sink opening 1110 for a coolant can be formed by forming female semiconductor wafer 120 to have openings 114 that remain empty, i.e., openings 114 located where there are no corresponding alignment projections 514, after structure 910 has been bonded to structure 920.

One of the advantages of the present invention is that the present invention provides a significant tolerance for alignment error. As the tolerance for alignment error increases, the less positional accuracy is required by the machine that brings semiconductor structures 910 and 920 together. The less positional accuracy that is required, the faster the machine can go, thereby increasing production.

For example, when semiconductor structures 910 and 920 are dice, a pick-and-place machine with less positional accuracy can be used to insert male semiconductor structure 910 into female semiconductor structure 920. The less positional accuracy that is required from the pick-and-place machine, the faster the pick-and-place machine can operate. Thus, as the tolerance for alignment error increases, the through-put volume increases.

FIGS. 12A-12B show views that illustrate an example of the alignment error tolerance of semiconductor structure 900 in accordance with the present invention. FIG. 12A shows a plan view, while FIG. 12B shows a cross-sectional view taken along lines 12B-12B of FIG. 12A. As shown in FIGS. 12A-12B, when the tip of a pyramid-shaped alignment projection 514 of semiconductor structure 910 is vertically aligned over the center of an inverted pyramid-shaped alignment opening 114 of semiconductor structure 920, the pyramidal shapes provide an alignment error tolerance up to a value E.

Thus, if a pick-and-place machine can position the tips of the alignment projections 514 to be vertically aligned over the centers of the inverted pyramid-shaped alignment openings 114, then the pick-and-place machine can tolerate an error in the positional accuracy up to the value E as shown in FIGS. 12A-12B. The value E can become quite large and, thereby, provide a significant tolerance for alignment error.

Another advantage of the present invention is that the present invention bonds the the male semiconductor die 910 to the female semiconductor structure 920 with a high degree of accuracy. The accuracy of the alignment is no longer primarily a function of the machine used to bring the two semiconductor structures together, but is a function of the accuracy by which the alignment openings 114 and alignment projections 514 can be formed.

Current-generation lithography systems are highly accurate. As a result, a number of alignment openings 114 and a corresponding number of alignment projections 514 can be formed with parallel side walls where the center-to-center spacing of the alignment openings 114 match the center-to-center spacing of the corresponding alignment projections 514 to a high degree of accuracy. Thus, the present invention allows precisely aligned die to be bonded together quickly and at a low cost.

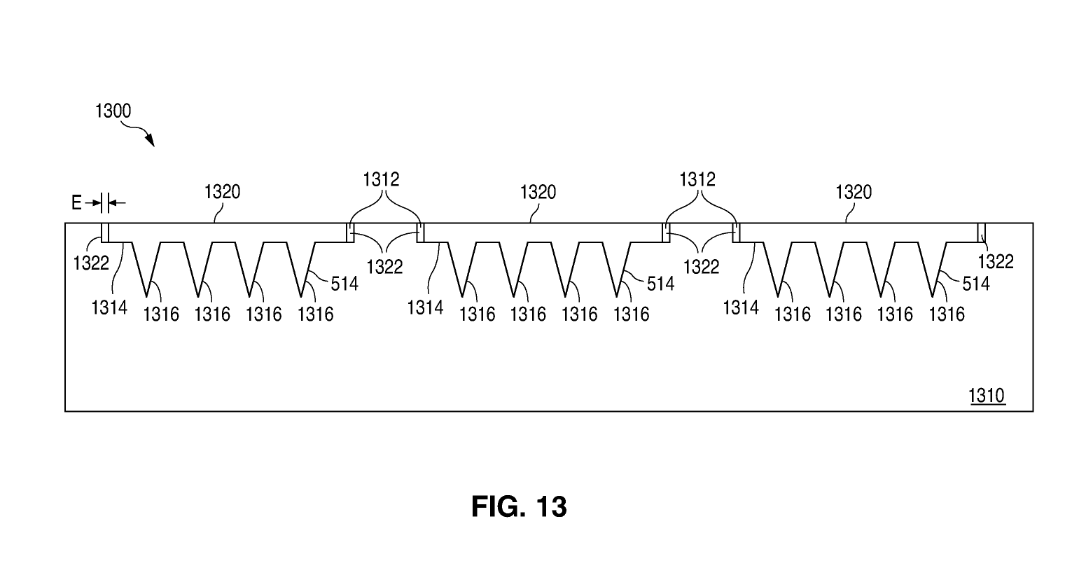

FIG. 13 shows a cross-sectional view that illustrates an example of a bonded semiconductor structure 1300 in accordance with an alternate embodiment of the present invention. As shown in FIG. 13, bonded semiconductor structure 1300 includes a female semiconductor structure 1310 that has a number of carrier openings 1312 formed in the top surface of female semiconductor structure 1310. Each carrier opening 1312, in turn, has a bottom surface 1314, and a number of alignment openings 1316 that are formed in the bottom surface 1314. The alignment openings 1316 are formed in the same way that the alignment openings 114 are formed.

As further shown in FIG. 13, bonded semiconductor structure 1300 includes a number of male semiconductor dice 1320 that each have a number of alignment projections 514 that are formed in the same way that the alignment projections 514 of male semiconductor structure 520 are formed.

The male semiconductor dice 1320, in turn, are placed within the carrier openings 1312 so that the alignment projections 514 on the dice 1320 are inserted into the alignment openings 1316. Because the maximum tolerance for alignment error is equal to the value E, the area of a carrier opening 1312 in the top surface of female semiconductor structure 1310 need only be 2E longer and 2E wider than the area required by a male semiconductor die 1320.

After the male semiconductor dice 1320 have been bonded to female semiconductor structure 1310, a gap 1322 lies between the side wall of each die 1320 and the side wall of structure 1310. Gap 1322, in turn, can be filled with a polymer, such as SU-8. (SU-8 contracts in response to extremely low temperatures, and is subject to pulling away from one side wall if the width of the gaps 1322 becomes too big.)

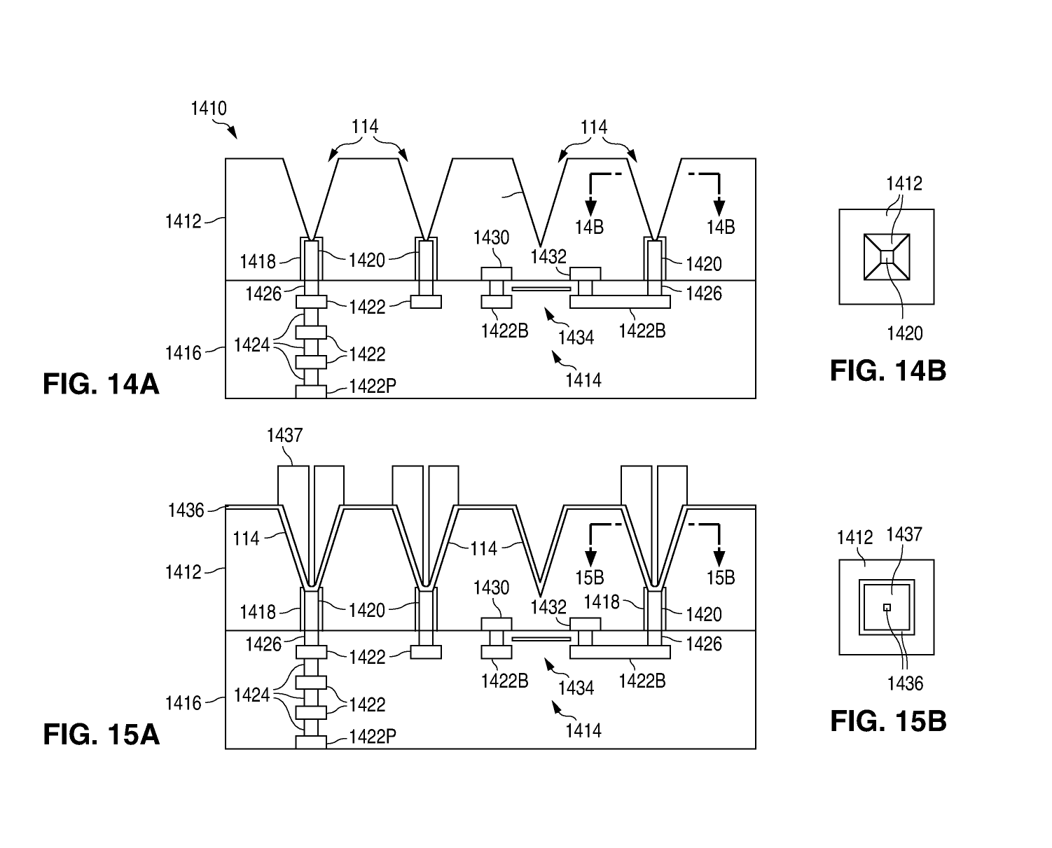

FIGS. 14A-14B through 23A-23B show views that illustrate an example of a method of forming a female semiconductor wafer in accordance with the present invention. FIGS. 14A-23A are cross-sectional views, while FIGS. 14B-23B are cross-sectional views taken along lines 14B-14B through 23B-23B of FIGS. 14A-23A, respectively.

As shown in FIGS. 14A-14B, the method utilizes a semiconductor wafer 1410 that is at or near the end of a conventional fabrication sequence (e.g., the bond pads may not yet be exposed). In the present example, semiconductor wafer 1410 includes a semiconductor substrate 1412 that has a number of spaced-apart electronic circuits 1414.

Wafer 1410 also includes a corresponding number of spaced-apart metal interconnect structures 1416 that are connected to the electronic circuits 1414 on the top surface of substrate 1412. (Only a part of one electronic circuit 1414 and metal interconnect structure 1416 are shown for clarity.) Semiconductor substrate 1412 can be implemented with a number of materials, such as silicon, gallium arsenic, or gallium nitride.

Each electronic circuit, in turn, includes a number of electrical devices, such as transistors, resistors, capacitors, diodes, isolation rings 1418, and deep contacts 1420 that are isolated from semiconductor substrate 1412 by the isolation rings 1418. The isolation rings 1418 and the deep contacts 1420 can be fabricated by forming deep holes in substrate 1412, lining the holes with oxide, and then filling the holes with a conductive material, e.g., a metallic material, as taught by U.S. Pat. No. 7,863,644 to Yegnashankaran et al., which is hereby incorporated by reference.

In addition, each metal interconnect structure 1416, which electrically connects the electrical devices together to form an electronic circuit, includes a number of levels of metal traces 1422, including a number of bottom metal traces 1422B and a number of top metal traces or pads 1422P. Metal interconnect structure 1416 also includes a large number of inter-metal vias 1424 that connect the metal traces 1422 in adjacent layers together.

Metal interconnect structure 1416 further includes a large number of contacts 1426 that connect the bottom metal traces 1422B to electrically conductive regions in the semiconductor substrate 1412, such as to the deep contacts 1420, and a source 1430 and a drain 1432 of a transistor 1434.

The method begins the same as the method illustrated in FIGS. 1A-1B through 4A-4B. As a result, as shown FIGS. 14A-14B, a number of alignment openings 114 are formed in substrate 1412 in the same manner that alignment openings 114 are formed in wafer 110, except that a number of deep contacts 1420 are also exposed by the alignment openings 114 in substrate 1412.

Thus, hard mask 112 is positioned so that the centers of a number of the openings through hard mask 112 are vertically aligned with the deep contacts 1420. For example, infra-red (IR) systems can be used to detect the location of the deep contacts 1420. This, in turn, allows the mask, which is used to pattern the photoresist layer that is used to pattern hard mask 112, to be precisely aligned with the deep contacts 1420 so that the centers of a number of the openings through hard mask 112 are vertically aligned with the deep contacts 1420.

Following the formation of the alignment openings 114 and the removal of hard mask 112, the method continues as shown in FIGS. 15A-15B with the conformal deposition of an isolation layer 1436 on substrate 1412 to line the alignment openings 114. Following this, a patterned photoresist layer 1437 is conventionally formed on isolation layer 1436 to expose the region of isolation layer 1436 that lies directly vertically over the deep contacts 1420.

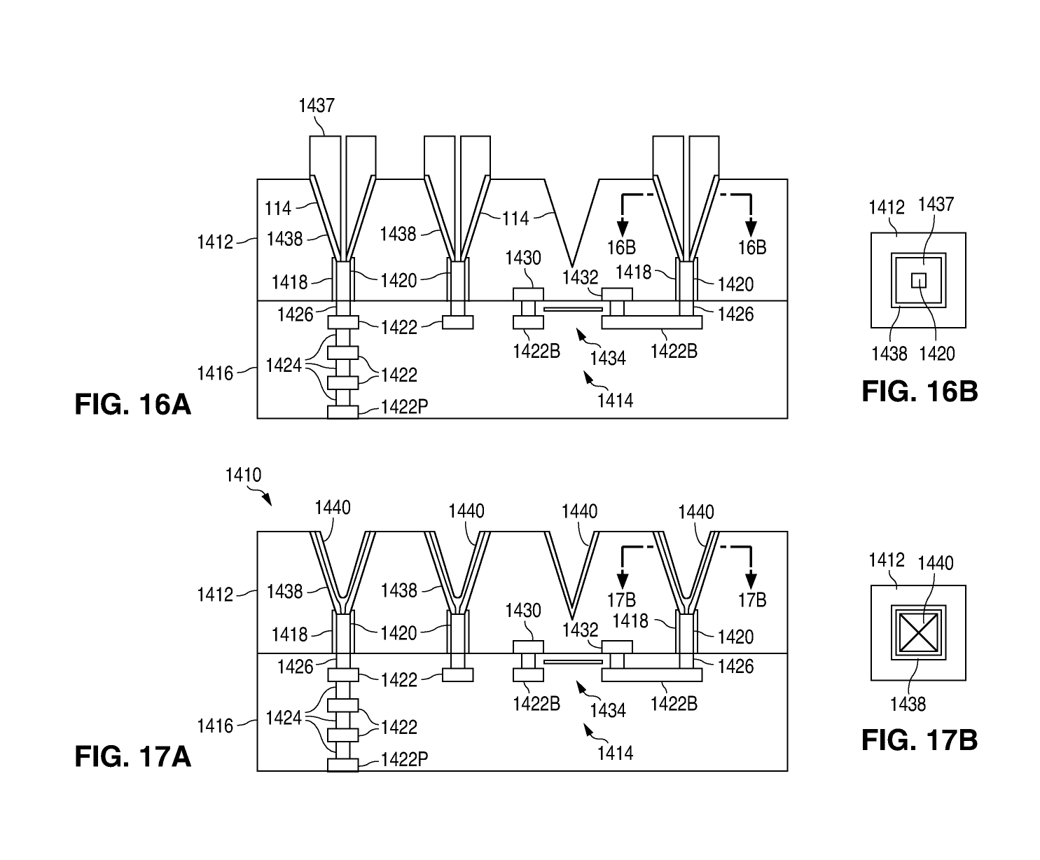

After this, as shown in FIGS. 16A-16B, the exposed regions of isolation layer 1436 are etched to expose the top surfaces of the deep contacts 1420 and form a number of isolation liners 1438 within each alignment opening 114. Once the etch is complete, patterned photoresist layer 1437 is removed using conventional materials and procedures.

As shown in FIGS. 17A-17B, following the formation of the isolation liners 1438, a number of metal liners 1440 are next formed in the alignment openings 114 to touch the isolation liners 1438 and the deep contacts 1420. The metal liners 1440 can be formed in a number of different ways.

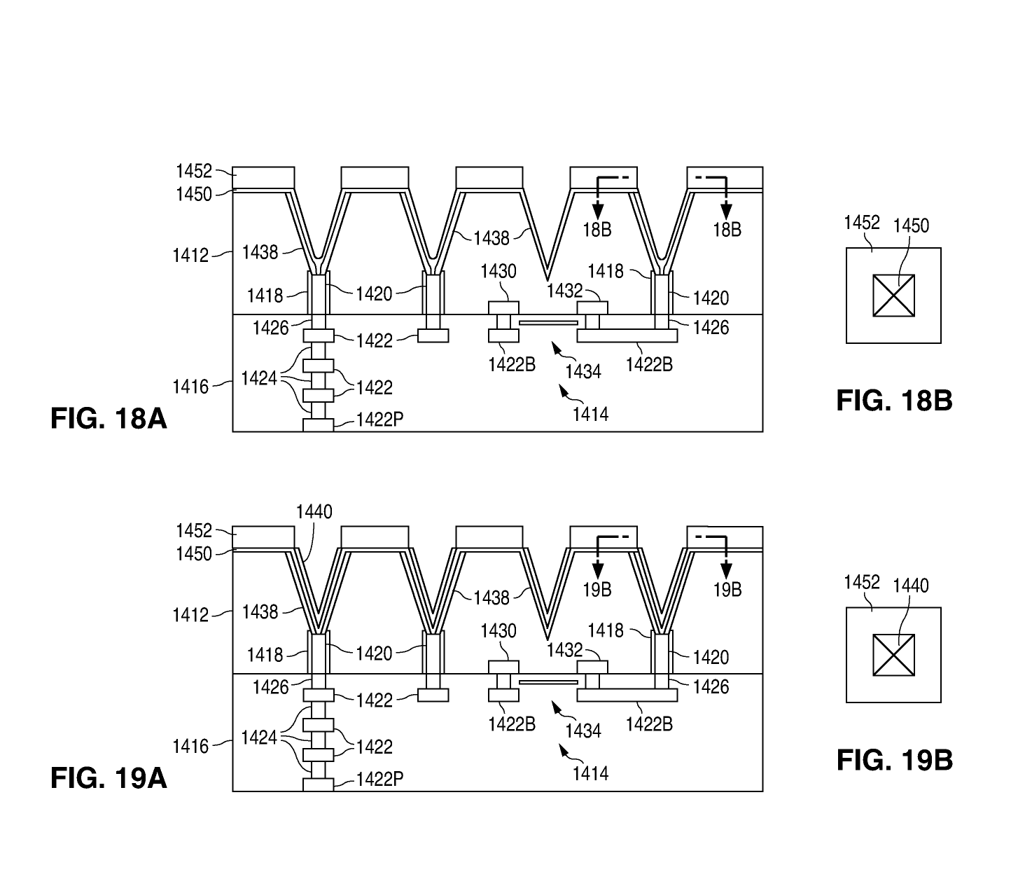

As shown in FIGS. 18A-18B, in a first embodiment, the metal liners 1440 can be fabricated by forming a seed layer 1450 that touches the bottom side of semiconductor substrate 1412, the isolation liners 1438, and the deep contacts 1420. For example, the seed layer 1450 can be formed by depositing 300 Å of titanium, 3000 Å of copper, and 300 Å of titanium. (The seed layer 1450 can also include a barrier layer to prevent copper electromigration if needed.) Once the seed layer 1450 has been formed, a plating mold 1452 is formed on the top surface of the seed layer 1450.

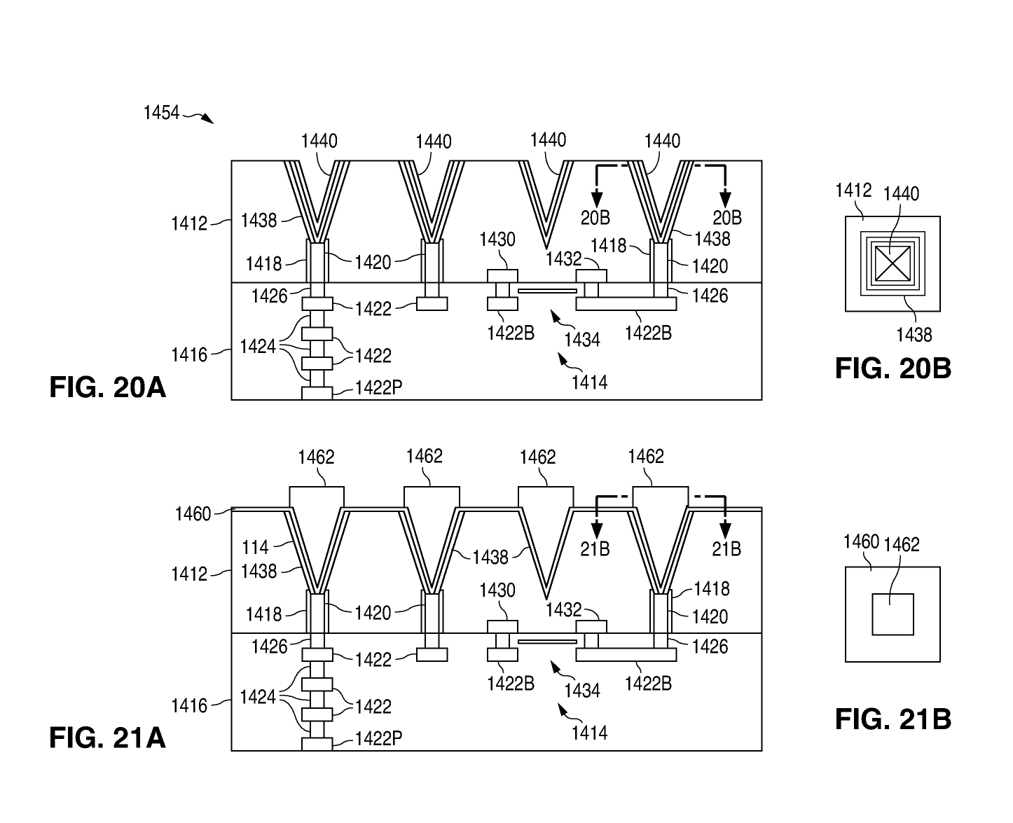

As shown in FIGS. 19A-19B, following the formation of the plating mold 1452, the top titanium layer is stripped and copper is deposited by electroplating to form the metal liners 1440. As shown in FIGS. 20A-20B, after the electroplating, the plating mold 1452 and the underlying regions of the seed layer 1450 are removed. Next, the bottom side of substrate 1412, the isolation liners 1438, and the metal liners 1440 are planarized to form a female semiconductor wafer 1454.

Alternately, in a second embodiment, as shown in FIGS. 21A-21B, the metal liners 1440 can be fabricated by forming a metal layer 1460 that touches the bottom side of substrate 1412, the isolation liners 1438, and the deep contacts 1420. Metal layer 1460 can include, for example, a layer of titanium (e.g., 100 Å thick), a layer of titanium nitride (e.g., 200 Å thick), a layer of aluminum copper (e.g., 1.2 μm thick), a layer of titanium (e.g., 44 Å thick), and a layer of titanium nitride (e.g., 250 Å thick). Once metal layer 1460 has been formed, a patterned photoresist layer 1462 is conventionally formed on the top surface of metal layer 1460.

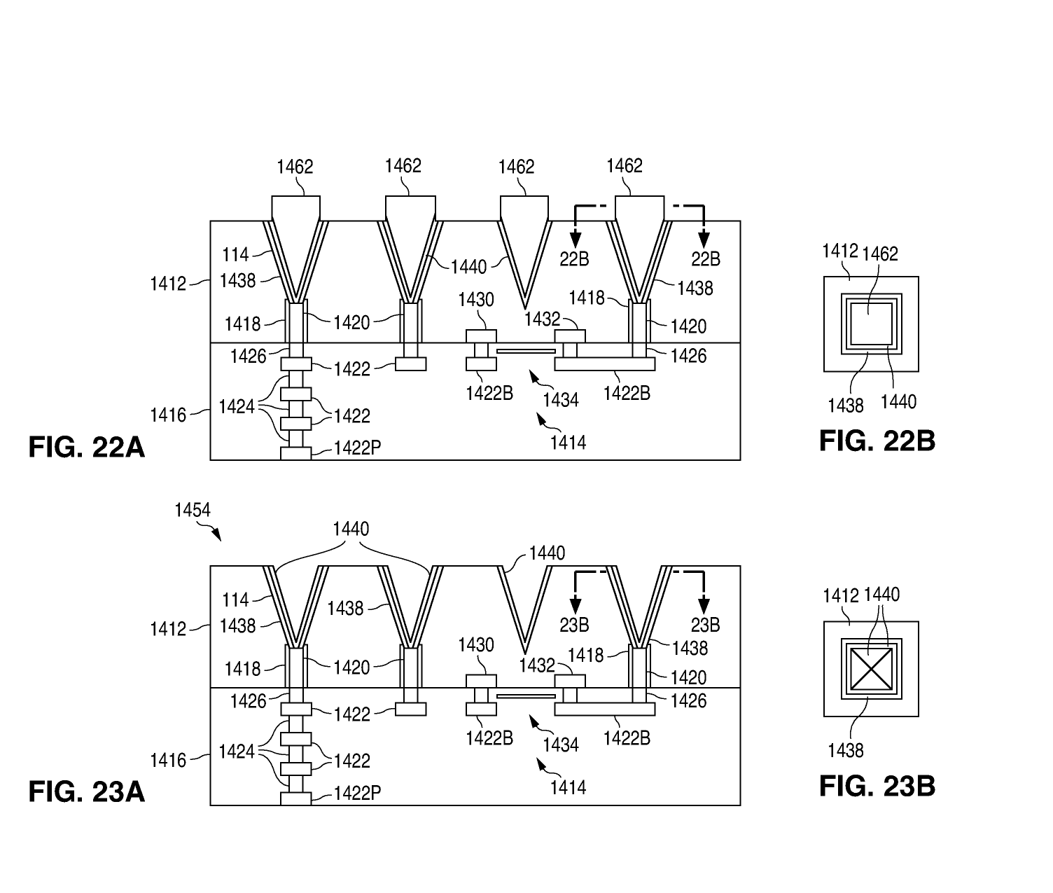

As shown in FIGS. 22A-22B, following the formation and patterning of mask 1462, metal layer 1460 is etched to remove the exposed region of metal layer 1460 and form the metal liners 1440. As shown in FIGS. 23A-23B, patterned photoresist layer 1462 is then removed using conventional materials and methods. Next, the bottom side of substrate 1412, the isolation liners 1438, and the metal liners 1440 are planarized to form female semiconductor wafer 1454.

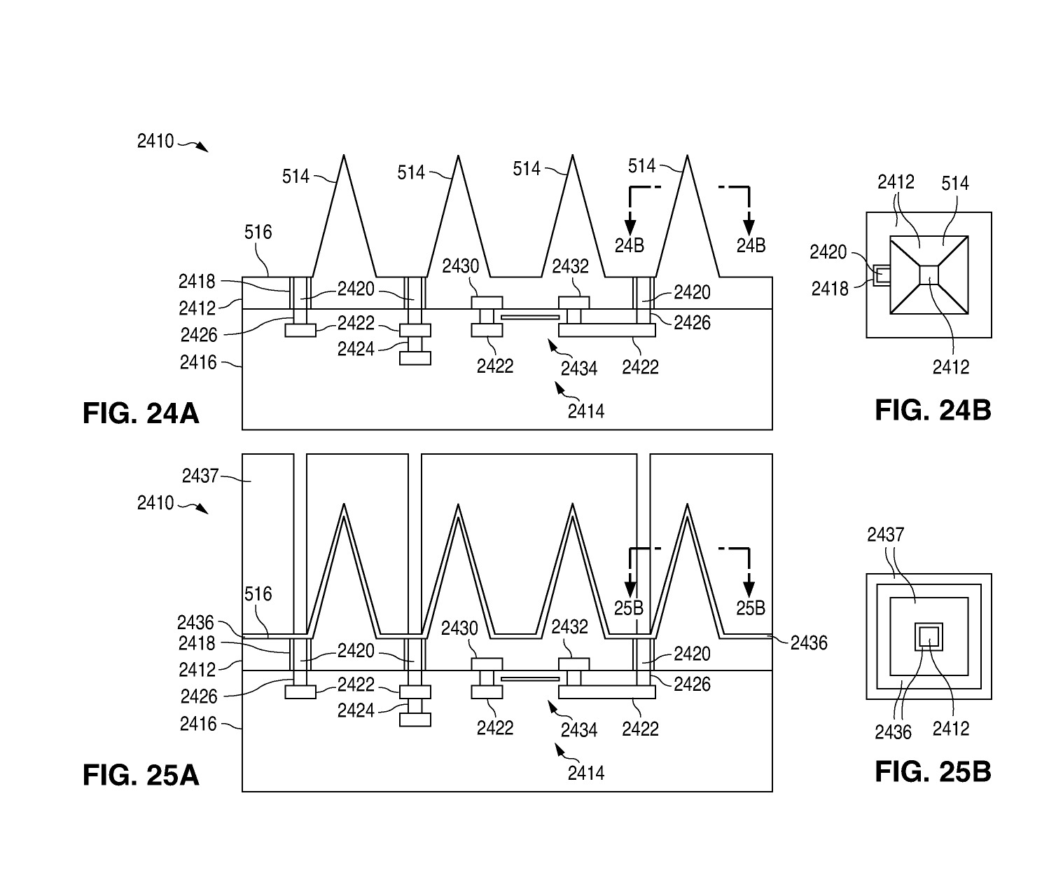

FIGS. 24A-24B through 33A-33B show views that illustrate an example of a method of forming a male semiconductor wafer in accordance with the present invention. FIGS. 24A-33A are cross-sectional views, while FIGS. 24B-33B are cross-sectional views taken along lines 24B-24B through 33B-33B of FIGS. 24A-33A, respectively.

As shown in FIGS. 24A-24B, the method utilizes a semiconductor wafer 2410 that is at or near the end of a conventional fabrication sequence (e.g., the bond pads may not yet be exposed). In the present example, semiconductor wafer 2410 includes a semiconductor substrate 2412 that has a number of spaced-apart electronic circuits 2414.

Wafer 2410 also includes a corresponding number of spaced-apart metal interconnect structures 2416 that are connected to the electronic circuits 2414 on the top surface of substrate 2412. (Only a part of one electronic circuit 2414 and metal interconnect structure 2416 are shown for clarity.) Semiconductor substrate 2412 can be implemented with a number of materials, such as silicon, gallium arsenic, or gallium nitride.

Each electronic circuit, in turn, includes a number of electrical devices, such as transistors, resistors, capacitors, diodes, and isolation rings 2418, and deep contacts 2420 that are isolated from semiconductor substrate 2412 by the isolation rings 2418. The isolation rings 2418 and the deep contacts 2420 can be fabricated by forming deep holes in substrate 2412, lining the holes with oxide, and then filling the holes with a conductive material, e.g., a metallic material.

In addition, each metal interconnect structure 2416, which electrically connects the electrical devices together to form an electronic circuit, includes a number of levels of metal traces 2422, including a number of bottom metal traces 2422B. Metal interconnect structure 2416 also includes a large number of inter-metal vias 2424 that connect the metal traces 2422 in adjacent layers together.

Further, metal interconnect structure 2416 includes a large number of contacts 2426 that connect the bottom metal traces 2422B to electrically conductive regions in the semiconductor substrate 2412, such as to the deep contacts 2420, and a source 2430 and a drain 2432 of a transistor 2434.

The method begins the same as the method illustrated in FIGS. 5A-5B through 8A-8B. As a result, as shown in FIGS. 24A-24B, a number of alignment projections 514 are formed on substrate 2412 in the same manner that alignment projections 514 are formed in wafer 510, except that a number of deep contacts 2420 are also exposed by planar surface 516.

Thus, hard mask 512 is positioned so that the deep contacts 2420 are exposed by planar surface 516. For example, infra-red (IR) systems can be used to detect the location of the deep contacts 2420. This, in turn, allows the mask, which is used to pattern the photoresist layer that is used to pattern hard mask 512, to be accurately positioned with respect to the deep contacts 2420 so that the deep contacts 2420 are exposed by planar surface 516.

Following the formation of the alignment projections 514 and the removal of hard mask 512, the method continues as shown in FIGS. 25A-25B with the conformal deposition of an isolation layer 2436 on substrate 2412 to cover the alignment projections 514. Following this, a patterned photoresist layer 2437 is conventionally formed on isolation layer 2436 to expose the regions of isolation layer 2436 that lie directly vertically over the deep contacts 2420.

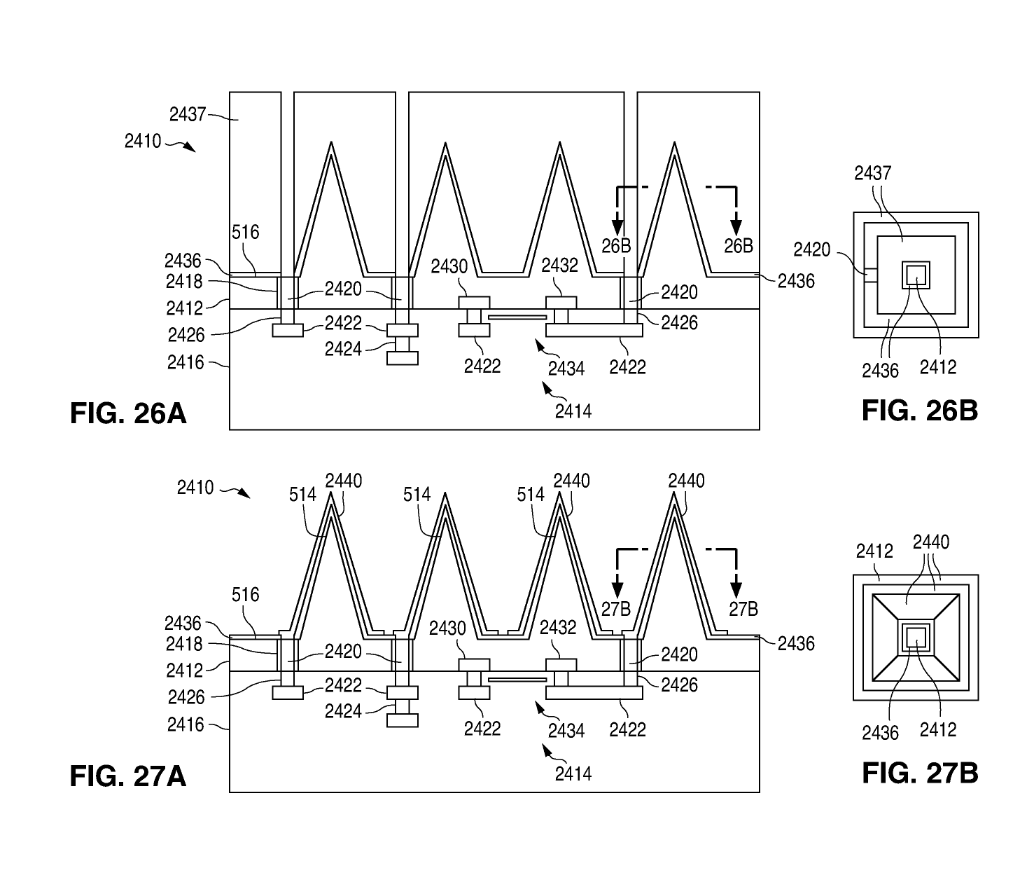

After this, as shown in FIGS. 26A-26B, the exposed regions of isolation layer 2436 are etched until regions on the top surfaces of the deep contacts 2420 have been exposed. Once the etch is complete, patterned photoresist layer 2437 is removed using conventional materials and procedures.

As shown in FIGS. 27A-27B, following the removal of patterned photoresist layer 2437, a number of metal covers 2440 are next formed over the alignment projections 514 to touch isolation layer 2436 and the deep contacts 2420. The metal covers 2440 can be formed in a number of different ways.

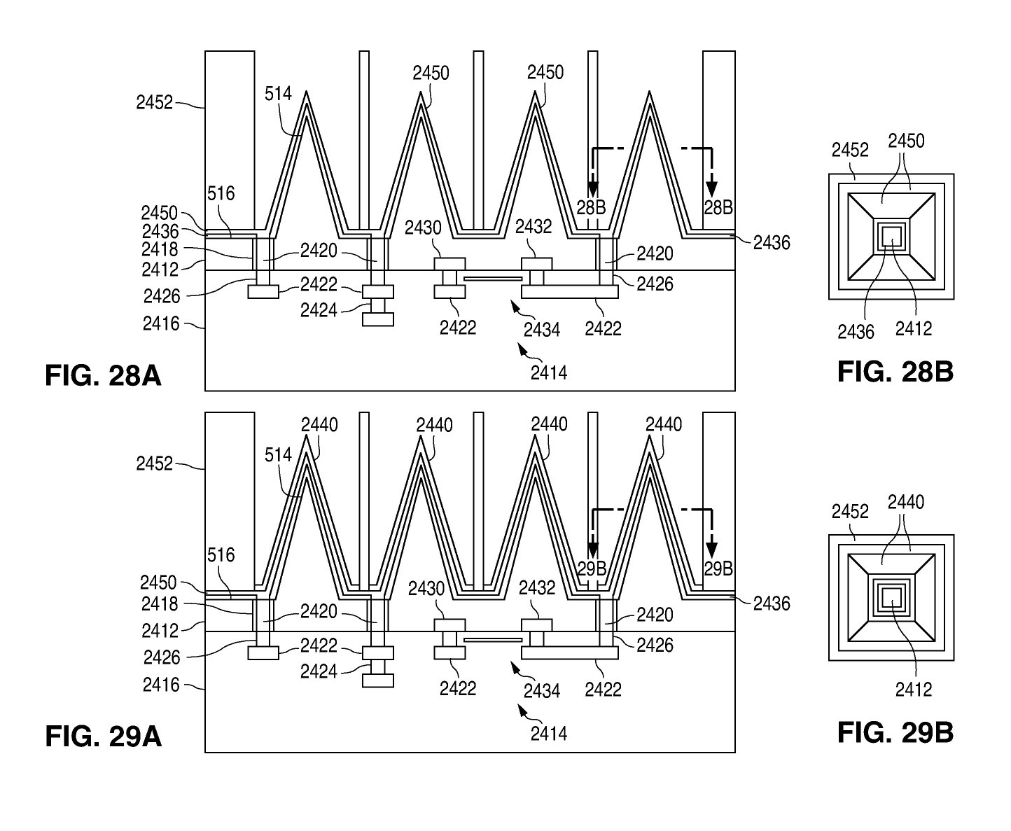

As shown in FIGS. 28A-28B, in a first embodiment, the metal covers 2440 can be fabricated by forming a seed layer 2450 over the alignment projections 514 to touch isolation layer 2436 and the exposed regions of the deep contacts 2420. For example, seed layer 2450 can be formed by depositing 300 Å of titanium, 3000 Å of copper, and 300 Å of titanium. (The seed layer 2450 can also include a barrier layer to prevent copper electromigration if needed.) Once the seed layer 2450 has been formed, a plating mold 2452 is formed on the top surface of the seed layer 2450.

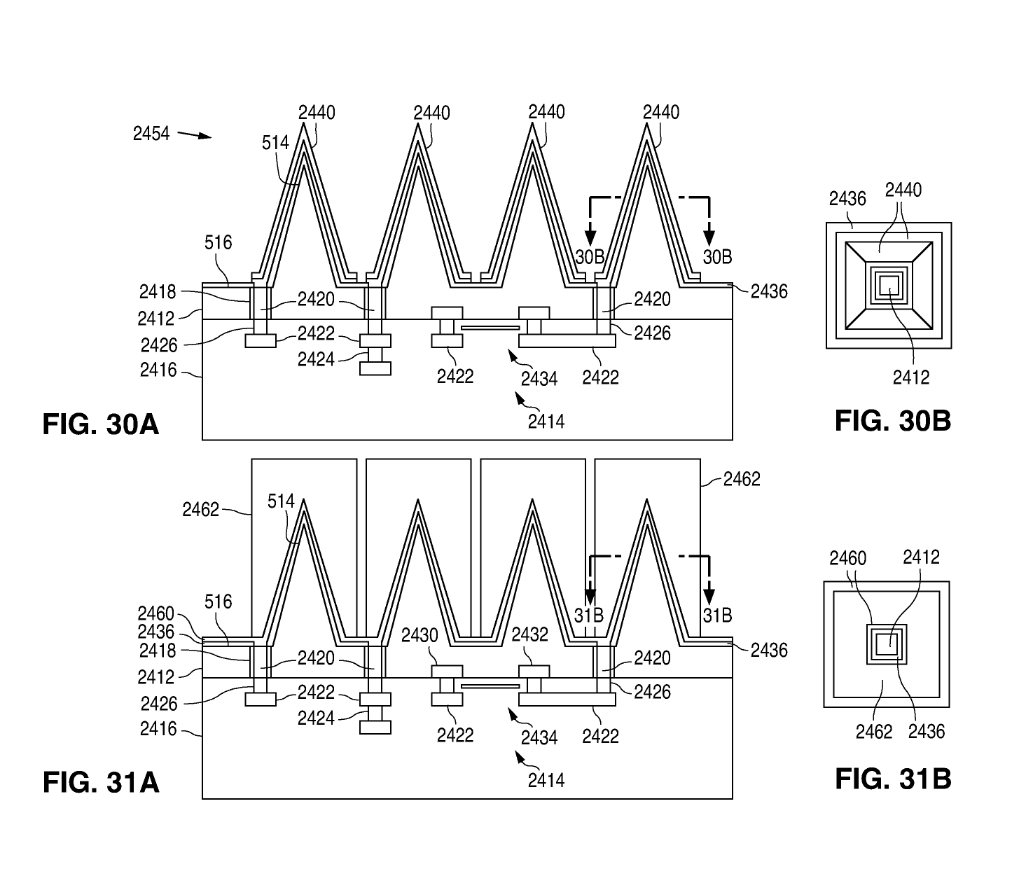

As shown in FIGS. 29A-29B, following the formation of the plating mold 2452, the top titanium layer is stripped and copper is deposited by electroplating to form the metal covers 2440. As shown in FIGS. 30A-30B, after the electroplating, the plating mold 2452 and the underlying regions of the seed layer 2450 are removed to form a male semiconductor wafer 2454.

Alternately, in a second embodiment, as shown in FIGS. 31A-31B, the metal covers 2440 can be fabricated by forming a metal layer 2460 over the alignment projections 514 to touch isolation layer 2436 and the exposed regions of the deep contacts 2420. Metal layer 2460 can include, for example, a layer of titanium (e.g., 100 Å thick), a layer of titanium nitride (e.g., 200 Å thick), a layer of aluminum copper (e.g., 1.2 μm thick), a layer of titanium (e.g., 44 Å thick), and a layer of titanium nitride (e.g., 250 Å thick). Once metal layer 2460 has been formed, a patterned photoresist layer 2462 is conventionally formed on the top surface of metal layer 2460.

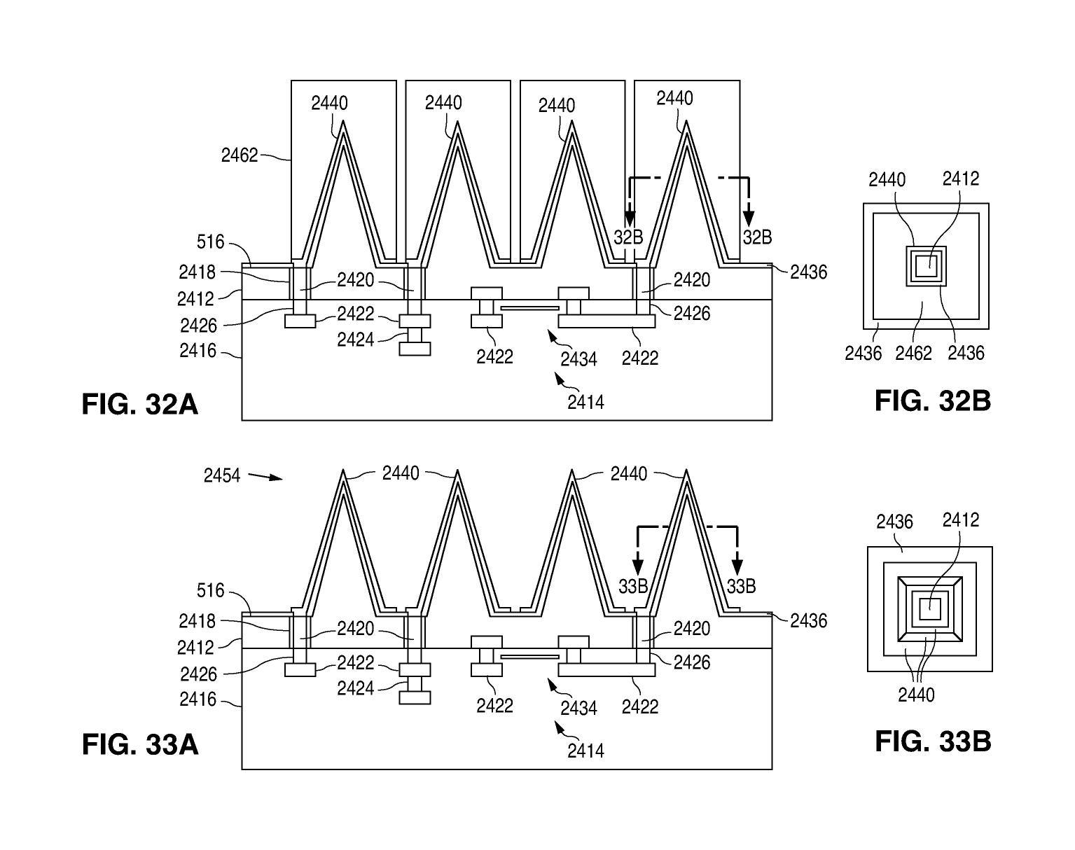

As shown in FIGS. 32A-32B, following the formation of patterned photoresist layer 2462, metal layer 2460 is etched to remove the exposed region of metal layer 2460 and form the metal covers 2440. As shown in FIGS. 33A-33B, patterned photoresist layer 2462 is then removed using conventional materials and methods to form male semiconductor wafer 2454.

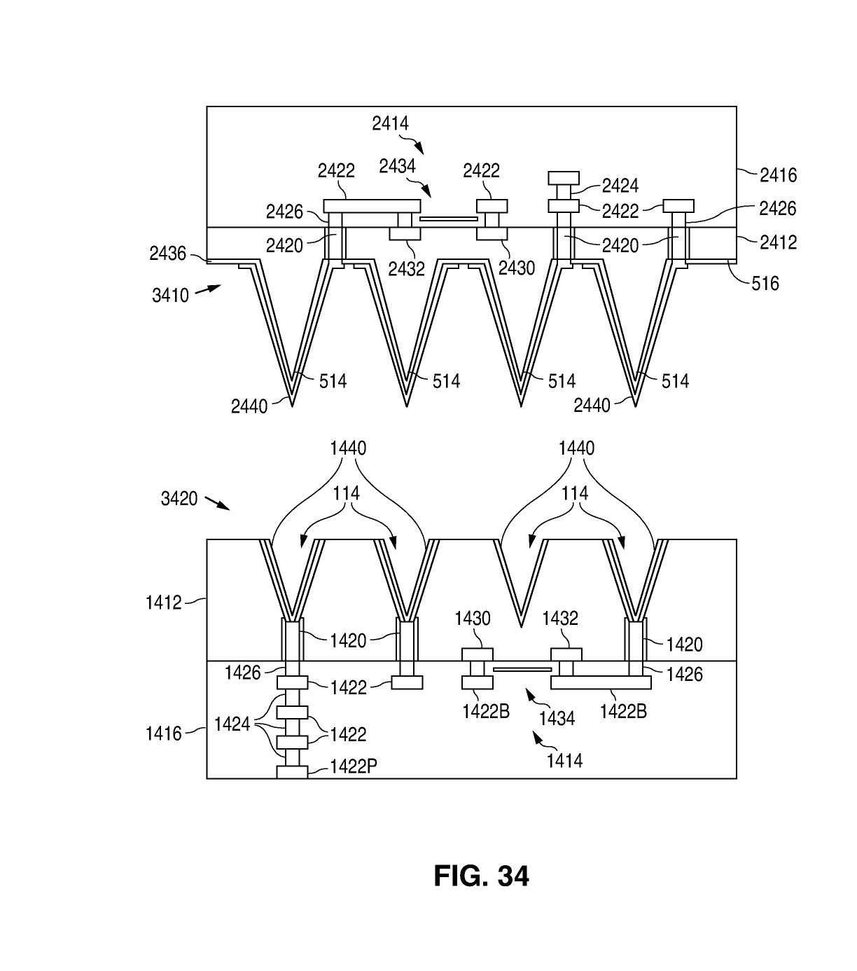

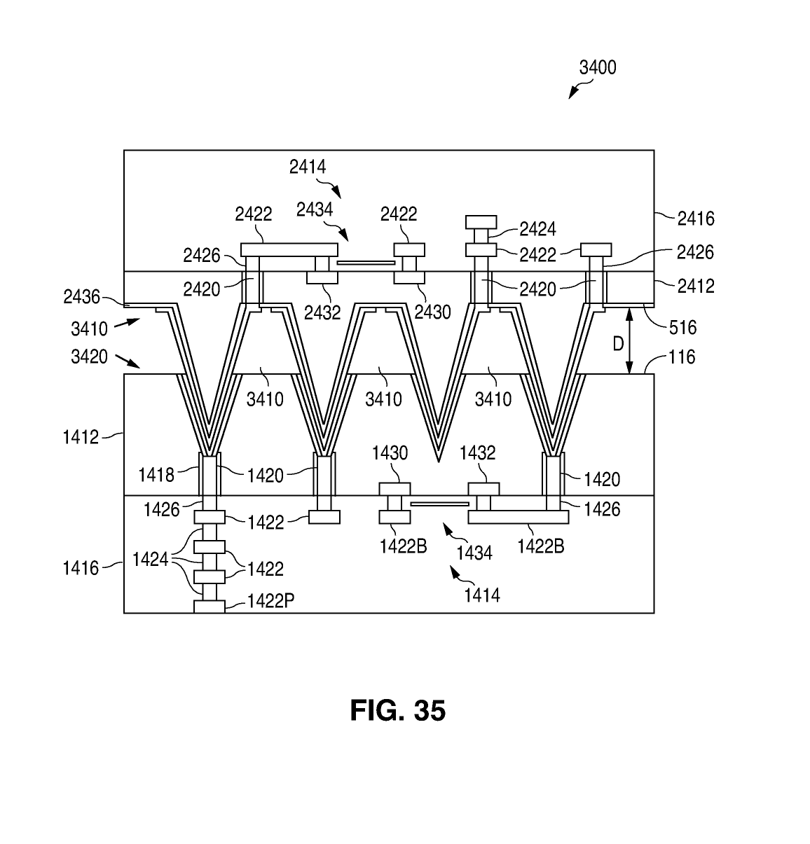

FIGS. 34-35 show cross-sectional views that illustrate an example of a method of forming a bonded semiconductor structure 3400 in accordance with the present invention. As shown in FIG. 34, the method begins by positioning the tips of the alignment projections 514 of a male semiconductor structure 3410 over the alignment openings 114 in a female semiconductor structure 3420.

Male semiconductor structure 3410 can be implemented with, for example, male semiconductor wafer 2454 or a die diced from male semiconductor wafer 2454, while female semiconductor structure 3420 can be implemented with female semiconductor wafer 1454 or a die diced from female semiconductor wafer 1454.

Following this, as shown in FIG. 35, the method applies any necessary bonding materials, inserts male semiconductor die 3410 into female semiconductor die 3420, and bonds male semiconductor die 3410 to female semiconductor die 3420 to form bonded semiconductor structure 3400.

Male semiconductor die 3410 can be bonded to female semiconductor die 3420 to form bonded semiconductor structure 3400 in a number of ways including, for example, solder bonding and eutectic bonding. To improve the bond, a bonding layer of, for example, nickel indium, silver indium, tin indium, or gold silver indium can optionally be formed on the metal liners 1440 and the metal covers 2440 before bonding.

For example, the bonding layer can be formed after seed layers 1450 and 2450 have been removed with a deposition, mask, and etch back process. The bonding layer can also be formed after metal layers 1460 and 2460 have been formed but before masks 1462 and 2462, respectively, have been formed.

As shown in FIGS. 34-35, the alignment openings 114 and the alignment projections 514 are in register so that each pyramid-shaped projection 514 fits into a corresponding pyramid-shaped alignment opening 114. In the FIG. 35 example, the planar surface 516 of die 3410 is separated from the planar surface 116 of die 3420 by a distance D, which can be varied by varying the sizes of the openings 114 and alignment projections 514. In addition, when the distance D is greater than zero, a number of die-to-die openings 3410, which can function as heat sink openings for a coolant, are formed when male semiconductor die 3410 is bonded to female semiconductor die 3420.

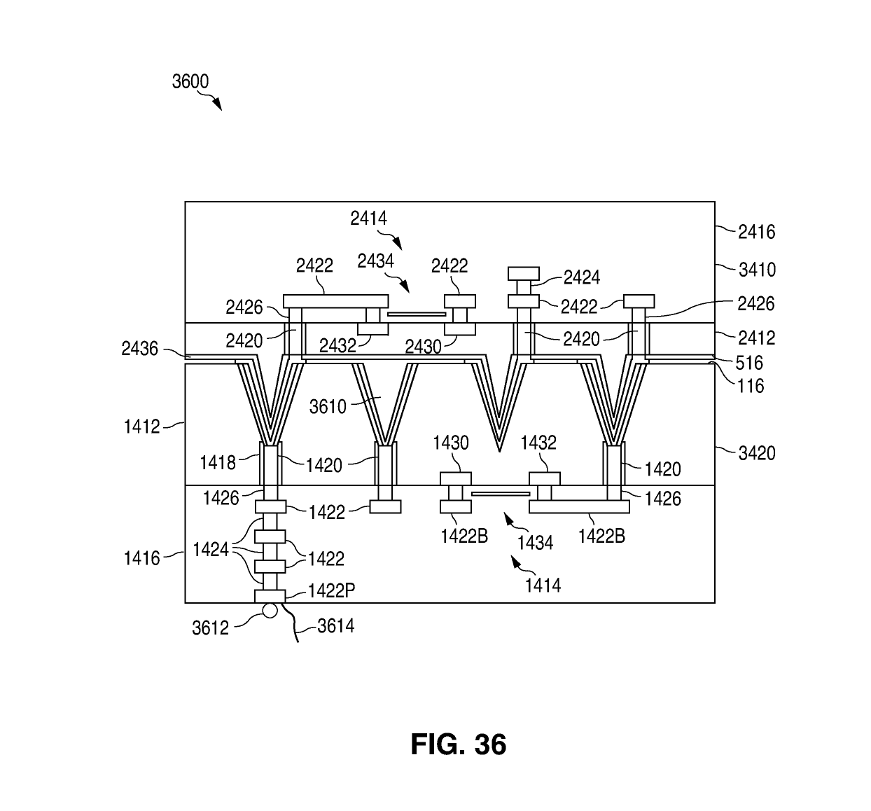

FIG. 36 shows a cross-sectional view that illustrates an example of a bonded semiconductor structure 3600 in accordance with an alternate embodiment of the present invention. The FIG. 36 example illustrates the case when the distance D is near zero so that the planar surface 516 of die 3410 nearly touches the planar surface 116 of die 3420. In addition, the FIG. 36 example illustrates that a heat sink opening 3610 can be formed by forming female semiconductor wafer 1454 to have openings 114 that remain empty, i.e., openings 114 located where there are no corresponding alignment projections 514, after die 3410 has been bonded to die 3420. Further, the FIG. 36 example illustrates that an external connection can be made by placing a solder ball 3612 or a bonding wire 3614 to touch pad 1422P.

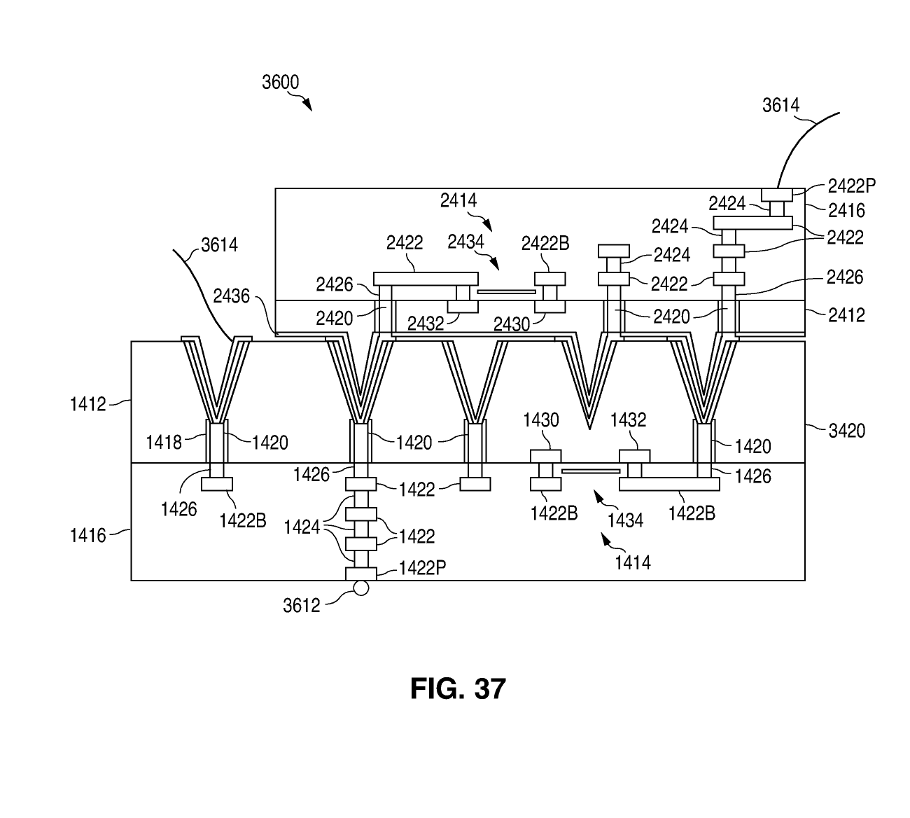

FIG. 37 shows a cross-sectional view that illustrates a further example of bonded semiconductor structure 3600 in accordance with an alternate embodiment of the present invention. The FIG. 37 example illustrates that the levels of metal traces 2422 also include a number of top metal traces or pads 2422P. In addition, the FIG. 37 example illustrates that a variety of external connections can be made to structure 3600 using solder balls 3612 and bonding wires 3614.

Thus, a method of bonding together a number of semiconductor structures has been described. The method first forms a female semiconductor structure with pyramid-shaped openings and a male semiconductor structure with pyramid-shaped projections, and then inserts the projections into the openings to align the male semiconductor structure to the female semiconductor structure for bonding.

It should be understood that the above descriptions are examples of the present invention, and that various alternatives of the invention described herein may be employed in practicing the invention. Thus, it is intended that the following claims define the scope of the invention and that structures and methods within the scope of these claims and their equivalents be covered thereby.

What is claimed is:

1. A semiconductor structure comprising a surface and a plurality of projections, each of the plurality of projections touching, being surrounded by, and extending out away from the surface, only the plurality of projections lying in a plane that lies substantially parallel to the surface.

2. The semiconductor structure of claim 1 and further comprising a layer of isolation material that touches the plurality of projections.

3. The semiconductor structure of claim 2 and further comprising a plurality of metal covers that lie over the plurality of projections, each metal cover being isolated from a corresponding projection by the layer of isolation material.

4. The semiconductor structure of claim 3 wherein a projection of the plurality of projections has a flat-topped pyramid shape.

5. The semiconductor structure of claim 3 wherein a projection of the plurality of projections has a pyramid shape.

6. A bonded semiconductor structure comprising:
a first semiconductor structure having a first surface and a plurality of projections, each of the plurality of projections touching, being surrounded by, and extending out away from the first surface, only the plurality of projections lying in a plane that lies substantially parallel to the first surface; and
a second semiconductor structure bonded to the first semiconductor structure, the second semiconductor structure having a second surface and a plurality of openings that extend from the second surface into the second semiconductor structure, the plurality of projections lying within the plurality of openings.

7. The bonded semiconductor structure of claim 6 and further comprising a layer of isolation material that touches the plurality of projections.

8. The bonded semiconductor structure of claim 7 and further comprising a plurality of metal covers that lie over the plurality of projections, each metal cover being isolated from a corresponding projection by the layer of isolation material.

9. The bonded semiconductor structure of claim 8 wherein a projection of the plurality of projections has a flat-topped pyramid shape.

10. The bonded semiconductor structure of claim 8 wherein a projection of the plurality of projections has a pyramid shape.

11. A method of forming a semiconductor device comprising:
forming a hard mask on a surface of a first semiconductor structure, the surface lying substantially in a plane; and
anisotropically wet etching an exposed region on the surface of the first semiconductor structure to form a plurality of projections so that only the hard mask and the plurality of projections remain lying in the plane, the plurality of projections being surrounded by and extending out away from an etched surface.

12. The method of claim 11 and further comprising:
removing the hard mask after the plurality of projections have been formed; and
inserting the plurality of projections into a plurality of openings in a second semiconductor structure.

13. The method of claim 12 and further comprising bonding the first semiconductor structure to the second semiconductor structure.

14. The method of claim 11 and further comprising:
removing the hard mask after the plurality of projections have been formed; and
forming a layer of isolation material to touch and cover the plurality of projections.

15. The method of claim 14 and further comprising forming a plurality of metal covers over the plurality of projections, each metal cover being isolated from a corresponding projection by the layer of isolation material.

16. The method of claim 15 and further comprising inserting the plurality of projections into a plurality of openings in a second semiconductor structure.

17. The method of claim 16 and further comprising bonding the first semiconductor structure to the second semiconductor structure.

18. The method of claim 15 wherein a projection of the plurality of projections has a pyramid shape.

19. The method of claim 15 wherein a projection of the plurality of projections has a flat-topped pyramid shape.
